(19) United States
(12) Patent Application Publication
(10) Pub. No.: US 2015/0144179 A1
(43) Pub. Date: May 28, 2015

(54) SOLAR CELL MODULE

(71) Applicant: AU Optronics Corporation, Hsin-Chu (TW)

(72) Inventors: Yung-Chih CHEN, Hsin-Chu (TW); Huang-Chi TSENG, Hsin-Chu (TW); Chieh-Min CHENG, Hsin-Chu (TW); Wen-Yuan LIAO, Hsin-Chu (TW)

(73) Assignee: AU Optronics Corporation, Hsin-Chu (TW)

(21) Appl. No.: 14/276,072

(22) Filed: May 13, 2014

(30) Foreign Application Priority Data
Nov. 27, 2013 (CN) 201310624502.7

(51) Int. Cl. H01L 31/042

(52) U.S. Cl. CPC H01L 31/0424
USPC 136/251

(57) ABSTRACT

A solar cell module includes a solar panel, a first frame strip, a second frame strip, and a connecting member. The first frame strip and the second frame strip are both assembled at the edges of the solar panel. The connecting member includes two top wind plates, a bottom wind plate, a connecting web, and two connecting terminal portions. A gap is formed between the two top wind plates. The connecting web is connected to the two top wind plates and the bottom wind plate, and has a breach and at least one corner. The breach and the gap form a drainage ditch to expose a corner of the solar panel. The two connecting terminal portions extend from the connecting web, so as to be detachably connected to the first frame strip and the second frame strip via the two connecting terminal portions.

### RELATED APPLICATIONS

This application claims priority to Chinese Application Serial Number 201310624502.7, filed Nov. 27, 2013, which is herein incorporated by reference.

### BACKGROUND

1. Field of Invention

The present invention relates to a solar cell module.

2. Description of Related Art

Human needs more and more energy with the advance of technology. Since oil reserve has been in shortage concerning the huge energy requirements of the human, scientists have greatly devoted into the research and development of new alternative energy. Among those, solar energy is one of the most desired new energies for the development.

A solar panel converts solar energy into electrical energy to provide useful electronic powers. The solar panels are normally disposed outdoors where the sunlight is available all the time, and the dust may cover the outdoor solar panel. The dust is able to be removed by rainwater or rinse; however, the solar panel is generally framed by frame stripes, and steps are formed at the edges of the solar panels, the dust washed out by the rainwater may be stuck at the steps of the solar panel. As a result, the stuck dust blocks the sunlight and reduces the incident flux of the sunlight, causing a low optical conversion efficiency.

### SUMMARY

An aspect of the present invention is to provide a solar cell module including a solar panel, at least one first frame strip, at least one second frame strip, and at least one connecting member. The first frame strip and the second frame strip are assembled at edges of the solar panel. The connecting member includes two top wind plates, a bottom wind plate, a connecting web, and two connecting terminal portions. A gap is formed between the two top wind plates. The bottom wind plate is disposed opposite to the two top wind plates. The connecting web is connected to the two top wind plates and the bottom wind plate. The connecting web has a breach and at least one corner. The breach is disposed at the corner and is connected to the gap, such that the breach and the gap form a drainage ditch, and the drainage ditch exposes at least one corner of the solar panel. The two connecting terminal portions respectively extend from the connecting web, such that the connecting member is detachably connected to the first frame strip and the second frame strip via the two connecting terminal portions.

Another aspect of the present invention is to provide a solar cell module including a solar panel, at least one first frame strip, at least one second frame strip, and at least one connecting member. The first frame strip and the second frame strip are assembled at edges of the solar panel. The connecting member is detachably connected to the first frame strip and the second frame strip, and the connecting member includes two top wind plates, a bottom wind plate, a connecting web, and a connecting portion. A gap is formed between the two top wind plates. The bottom wind plate is disposed opposite to the two top wind plates. The connecting web is connected to the two top wind plates and the bottom wind plate, such that the two top wind plate, the bottom wind plate, and the connecting web together define an accommodating recess. The connecting web has a breach and at least one corner. The breach is disposed at the corner and is connected to the gap, such that the breach and the gap form a drainage ditch, and the drainage ditch exposes at least one corner of the solar panel. The connecting portion is at least disposed in the accommodating recess, and is detachably connected to the first frame strip and the second frame strip.

### BRIEF DESCRIPTION OF THE DRAWINGS

FIG. 1 is a three dimensional view of a solar cell module according to the first embodiment of the present invention;

FIG. 2A is a front view of a connecting member of FIG. 1;

FIG. 2B is a back view of the connecting member of FIG. 1;

FIG. 3 is a three dimensional view of a solar cell module according to the second embodiment of the present invention;

FIG. 4 is a front view of the connecting member of FIG. 3;

FIG. 5A is a front view of the connecting member of FIG. 4 after assembled; and

FIG. 5B is a back view of the connecting member of FIG. 5A.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

### The First Embodiment

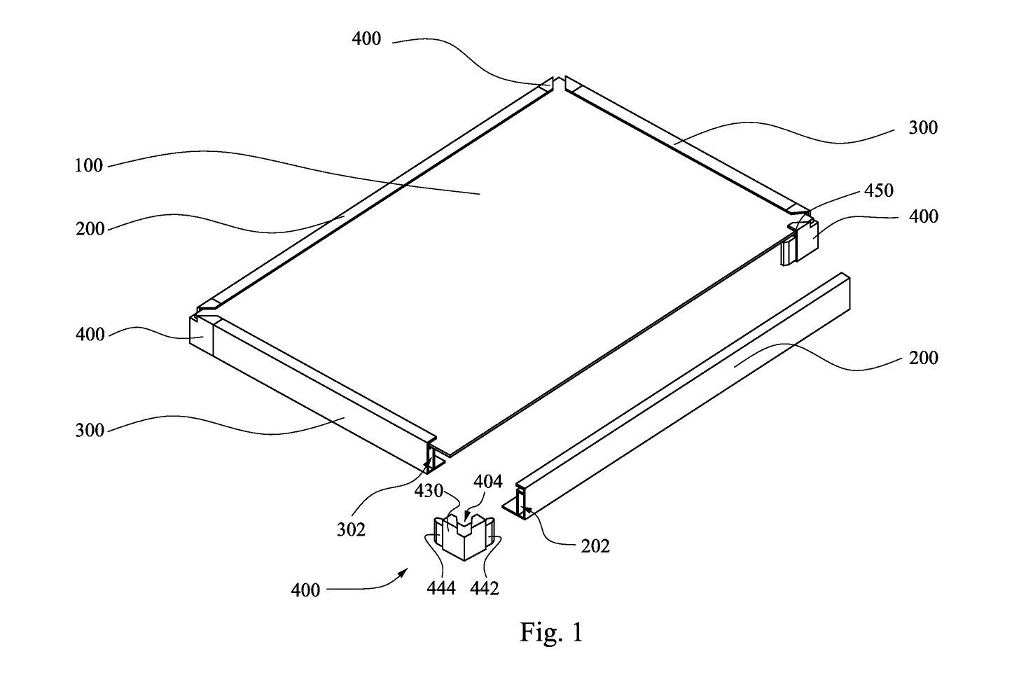

FIG. 1 is a three dimensional view of a solar cell module according to the first embodiment of the present invention. The solar cell module includes a solar panel 100, at least one first frame strip 200, at least one second frame strip 300, and at least one connecting member 400. The first frame strip 200 and the second frame strip 300 are assembled (framed) at edges of the solar panel 100. For example, the solar cell module may include two of the first frame strips 200 and two of the second frame strips 300 as shown in FIG. 1. The two first frame strips 200 can be disposed opposite to each other, and the two second frame strips 300 can be disposed opposite to each other. The connecting member 400 is detachably connected to the first frame strip 200 and the second frame strip 300.

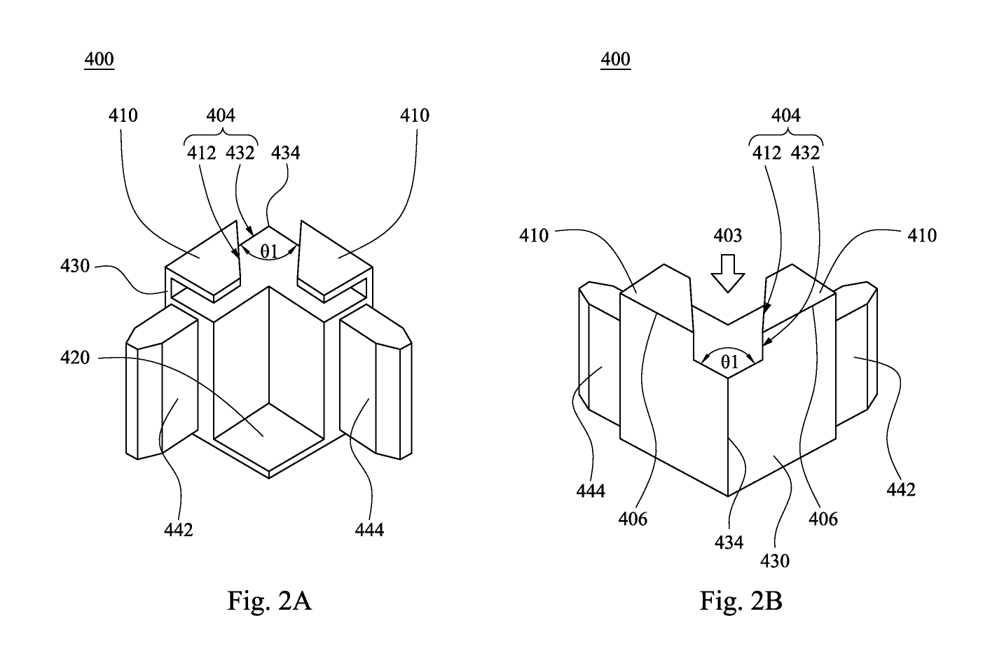

FIG. 2A is a front view of the connecting member 400 of FIG. 1, and FIG. 2B is a back view of the connecting member 400 of FIG. 1. Reference is made to FIGS. 2A and 2B. In greater detail, the connecting member 400 includes two top wind plates 410, a bottom wind plate 420, a connecting web 430, and two connecting terminal portions 442 and 444. A gap 412 is formed between the two top wind plates 410. The bottom wind plate 420 is disposed opposite to the two top wind plates 410. The connecting web 430 is connected to the two top wind plates 410 and the bottom wind plate 420. The connecting web 430 has a breach 432 and at least one corner 434. The breach 432 is disposed at the corner 434 and is connected to the gap 412, such that the breach 432 and the gap 412 form a drainage ditch 404. The two connecting terminal portions 442 and 444 respectively extend from the connecting web 430, such that the connecting member 400 is detachably connected to the first frame strip 200 and the second frame strip 300 (both see FIG. 1) via the two connecting terminal portions 442 and 444.

Reference is made to FIGS. 1 and 2A. More specifically, since the connecting member 400 of the present invention has the drainage ditch 404, the rainwater can scour the dust that is stuck on the solar cell module to the drainage ditch 404, and the rainwater can remove the dust out of the solar cell module along the drainage ditch 404. Accordingly, the solar cell module can be clean so as to prevent the dust from blocking the sunlight incident to the solar panel 100. In addition, the connecting member 400 in this embodiment is detachably connected to the first frame strip 200 and the second frame strip 300. Even though the connecting member 400 is damaged, or the dust is stuck in the drainage ditch 404 of the connecting member 400, the connecting member 400 can be detached from the first frame strip 200 and the second frame strip 300 to be replaced or be cleaned. In other words, the connecting member 400 is convenient to be detached and assembled.

In one or more embodiments, the two connecting terminal portions 442 and 444 can be two terminal portions of the same connecting element (not shown). For example, the connecting web 430 can cover a portion of the connecting element, such that the two connecting terminal portions 442 and 444 can be exposed and extend from the connecting web 430. The connecting element can be made from metal so as to have a strong structure. The connecting web 430 can be made from plastic, and can cover the connecting element using injecting molding technique. In addition, the top wind plates 410 and the bottom wind plate 420 can be made from plastic, and the claimed scope is not limited in this respect.

Reference is made again to FIG. 2B. In this embodiment, an angle θ1 is formed at the corner 434 of the connecting web 430 of the connecting member 400, and the angle θ1 is about 90 degrees. In other words, the connecting web 430 can be L-shaped. Reference is made again to FIG. 1. The extending directions of the first frame strip 200 and the second frame strip 300 intersect with each other at an angle about 90 degrees if the solar panel 100 is rectangular-shaped. In other words, the connecting member 400 can be disposed at the corner of the solar panel 100 to expel the rainwater and the dust from the corner of the solar cell module.

Reference is made again to FIG. 2B. In one or more embodiments, the two top wind plates 410 of the connecting member 400 can be symmetric with respect to the gap 412, and the gap 412 has two sides substantially parallel to each other. Therefore, if the angle θ1 of the corner 434 of the connecting web 430 is about 90 degrees, an extending direction 403 of the gap 412 intersects with an adjoining line 406 of one of the top wind plates 410 and the connecting web 430 at an angle about 45 degrees. It is noted that the type of the gap 412 is not limited in the respect of FIG. 2B. In other embodiments, the two top wind plates 410 can both be rectangular. That is, the width of the gap 212 goes wider as towards the breach 432 so as to avoid sharp corners at the top wind plates 410. Furthermore, the top wind plates 410 may have chamfers, and the claimed scope is not limited in this respect.

Reference is made again to FIG. 1. In this embodiment, the connecting terminal portions 442 and 444 can be respectively connected to the first frame strip 200 and the second frame strip 300 to fix the relative position between the first frame strip 200 and the second frame strip 300. For example, the first frame strip 200 may have a first groove 202, and the second frame strip 300 may have a second groove 302. The connecting terminal portion 442 is configured to be inserted to the first groove 202, and the connecting terminal portion 444 is configured to be inserted to the second groove 302. As such, the connecting member 400 can be connected to the first frame strip 200 and the second frame strip 300. Moreover, the outer surface of the connecting web 430 of the connecting member 400 can be aligned with the outer surfaces of the first frame strip 200 and the second frame strip 300 when the connecting member 400 is connected to the first frame strip 200 and the second frame strip 300. In other words, the connecting web 430 is not bumped out from the first frame strip 200 and the second frame strip 300, leading to a well integrity of the solar cell module. This configuration not only possesses safety consideration, but also improves the beautification of the solar cell module. However, the claimed scope is not limited in this respect.

Reference is made again to FIGS. 1 and 2A. In one or more embodiments, the drainage ditch 404 of the connecting member 400 can expose at least one corner of the solar panel 100. In other words, the rainwater may flow out of the solar cell module along the exposed corner. Therefore, since there is no height difference (step difference) along the flow path of the rainwater, the dust is not stuck in the slits of the step, and the flow of the rainwater is not impeded by the step.

It is noted that the solar cell module includes four connecting members 400 in FIG. 1, and the claimed scope is not limited in this respect. In other embodiments, the solar cell module may include at least one connecting member 400 to be connected to the first frame strip 200 and the second frame strip 300 while the connection way between other first frame strips 200 and the second frame strips 300 is not limited. Moreover, the shapes of the first frame strip 200 and the second frame strip 300 depend on the shape of the solar panel 100. Basically, an embodiment falls within the scope of the claimed scope if both of the first frame strip 200 and the second frame strip 300 can fix (frame) the solar panel 100.

### The Second Embodiment

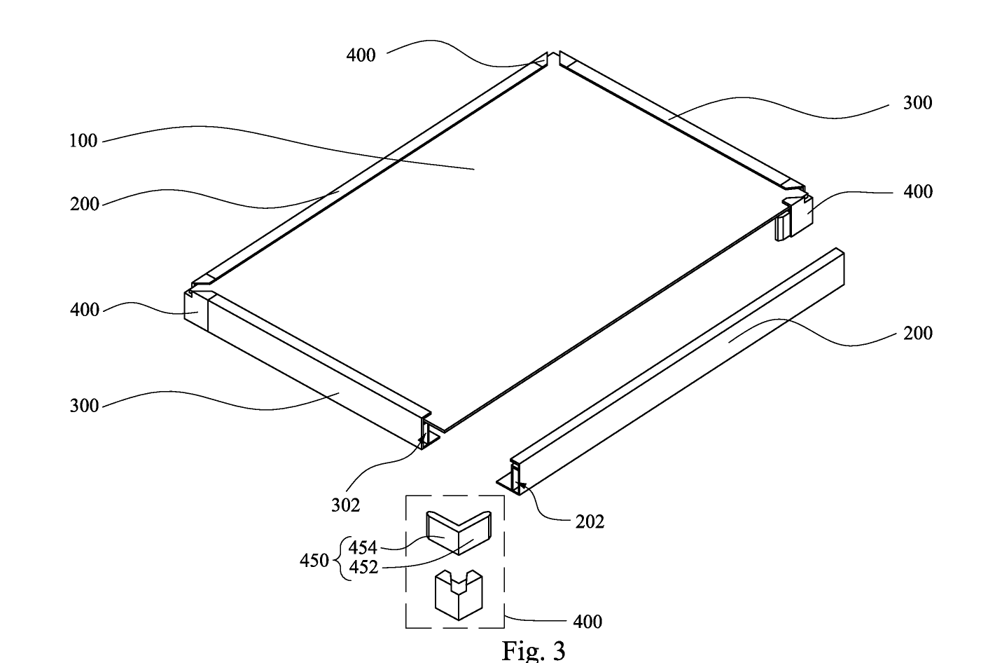

FIG. 3 is a three dimensional view of a solar cell module according to the second embodiment of the present invention. The solar cell module includes a solar panel 100, at least one first frame strip 200, at least one second frame strip 300, and at least one connecting member 400. The first frame strip 200 and the second frame strip 300 are assembled (framed) at edges of the solar panel 100. For example, the solar cell module may include two of the first frame strips 200 and two of the second frame strips 300 as shown in FIG. 3. The two first frame strips 200 can be disposed opposite to each other, and the two second frame strips 300 can be disposed opposite to each other. The connecting member 400 is detachably connected to the first frame strip 200 and the second frame strip 300.

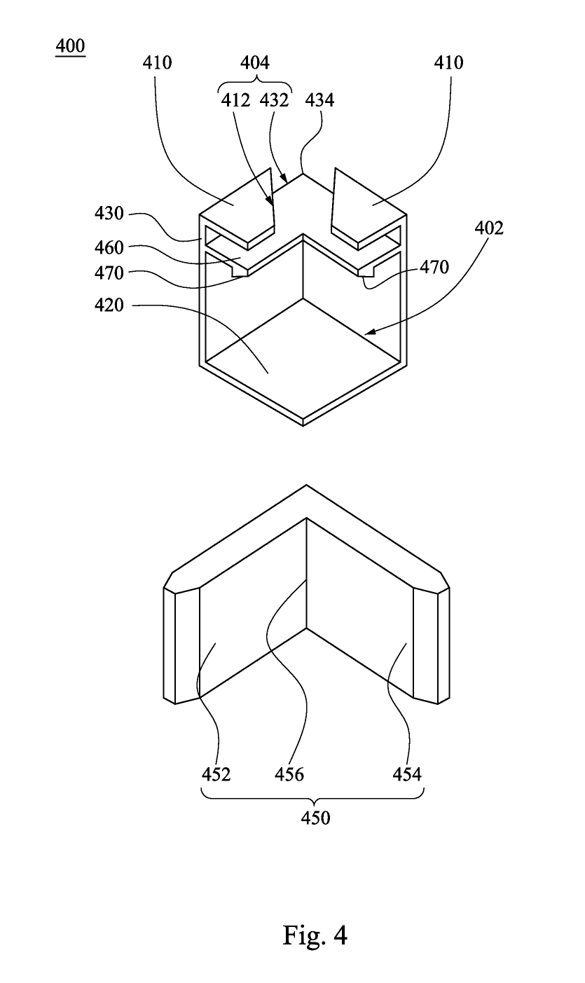

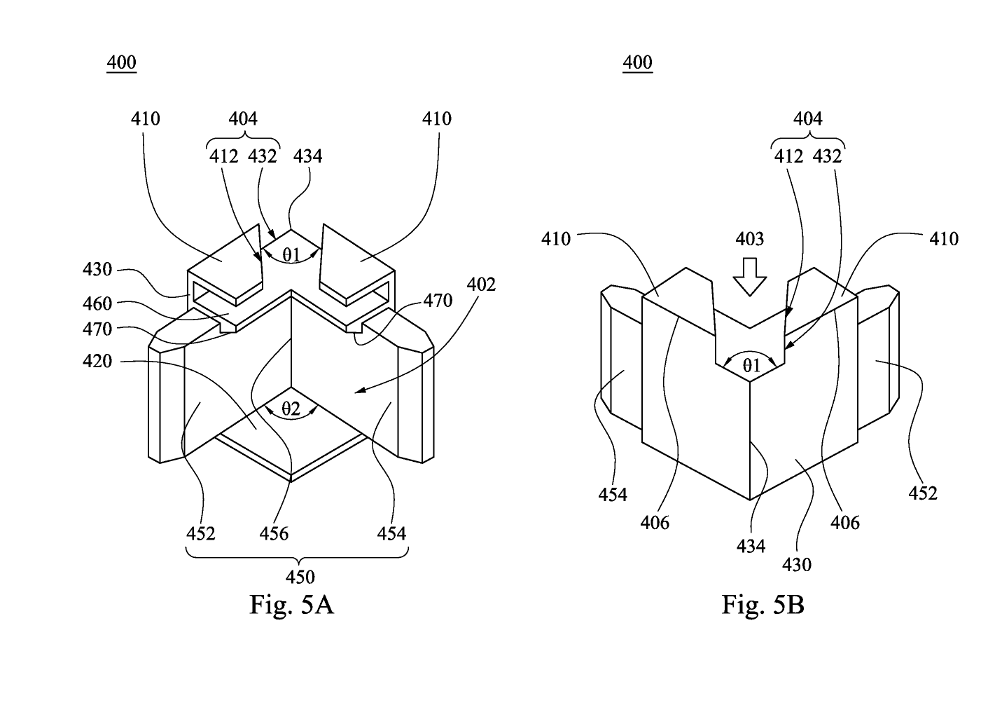

FIG. 4 is a front view of the connecting member 400 of FIG. 3, FIG. 5A is a front view of the connecting member 400 of FIG. 4 after assembled, and FIG. 5B is a back view of the connecting member 400 of FIG. 5A. Reference is made to FIGS. 4 to 5B. In greater detail, the connecting member 400 includes two top wind plates 410, a bottom wind plate 420, a connecting web 430, and a connecting portion 450. A gap 412 is formed between the two top wind plates 410. The bottom wind plate 420 is disposed opposite to the two top wind plates 410. The connecting web 430 is connected to the two top wind plates 410 and the bottom wind plate 420, such that the two top wind plates 410, the bottom wind plate 420, and the connecting web 430 together define an accommodating recess 402. The connecting web 430 has a breach 432 and at least one corner 434. The breach 432 is disposed at the corner 434 and is connected to the gap 412, such that the breach 432 and the gap 412 form a drainage ditch 404. The connecting portion 450 is at least disposed in the accommodating recess 402, and is detachably connected to the first frame strip 200 and the second frame strip 300 (both see FIG. 3).

Reference is made to FIGS. 3 and 4. More specifically, since the connecting member 400 of the present invention has the drainage ditch 404, the rainwater can scour the dust that is stuck on the solar cell module to the drainage ditch 404, and the rainwater can remove the dust out of the solar cell module along the drainage ditch 404. Accordingly, the solar cell module can be clean so as to prevent the dust from blocking sunlight incident to the solar panel 100. In addition, the connecting member 400 in this embodiment is detachably connected to the first frame strip 200 and the second frame strip 300. Even though the connecting member 400 is damaged, or the dust is stuck in the drainage ditch 404 of the connecting member 400, the connecting member 400 can be detached from the first frame strip 200 and the second frame strip 300 to be replaced or be cleaned. In other words, the connecting member 400 is convenient to be detached and assembled.

Reference is made again to FIG. 4. In this embodiment, the connecting portion 450 may have at least one corner 456 disposed adjacent to the corner 434 of the connecting web 430. In other words, the corner 456 of the connecting portion 450 aligns with the corner 434 of the connecting web 430. Furthermore, the connecting web 430 can be disposed adjacent to the connecting portion 450, and the claimed scope is not limited in this respect. Basically, an embodiment falls within the claimed scope of the invention if at least a portion of the connecting portion 450 is disposed in the accommodating recess 402, and the connecting portion 450 can be detachably connected to the first frame strip 200 and the second frame strip 300 (both see FIG. 3).

Reference is made again to FIG. 5B. In this embodiment, an angle θ1 is formed at the corner 434 of the connecting web 430 of the connecting member 400, and the angle θ1 is about 90 degrees. In other words, the connecting web 430 can be L-shaped. Reference is made again to FIG. 3. The extending directions of the first frame strip 200 and the second frame strip 300 intersect with each other at an angle about 90 degrees if the solar panel 100 is rectangular-shaped. In other words, the connecting member 400 can be disposed at the corner of the solar panel 100 to expel the rainwater and the dust from the corner of the solar cell module. Moreover, reference is made again to FIG. 5A. The corner 456 of the connecting portion 450 can have an angle 82. The value of the angle θ2 is equal to that of angle θ1, that is, the angle 82 is also about 90 degree. However, the claimed scope of the present invention is not limited in this respect.

Reference is made again to FIG. 5B. In one or more embodiments, the two top wind plates 410 of the connecting member 400 can be symmetric with respect to the gap 412, and the gap 412 has two sides substantially parallel to each other. Therefore, if the angle θ1 of the corner 434 of the connecting web 430 is about 90 degrees, an extending direction 403 of the gap 412 intersects with an adjoining line 406 of one of the top wind plates 410 and the connecting web 430 at an angle about 45 degrees. It is noted that the type of the gap 412 is not limited in the respect of FIG. 5B. In other embodiments, the two top wind plates 410 can both be rectangular. That is, the width of the gap 212 goes wider as towards the breach 432 so as to avoid sharp corners at the top wind plates 410. Furthermore, the top wind plates 410 may have chamfers, and the claimed scope is not limited in this respect.

Reference is made again to FIG. 5A. In this embodiment, the connecting portion 450 has two terminal portions 452 and 454 opposite to each other. The terminal portions 452 and 454 extend from the accommodating recess 402, respectively. The terminal portions 452 and 454 can be respectively connected to the first frame strip 200 and the second frame strip 300 to fix the relative position between the first frame strip 200 and the second frame strip 300. For example, reference is made again to FIG. 3. In this embodiment, the first frame strip 200 may have a first groove 202, and the second frame strip 300 may have a second groove 302. The terminal portion 452 of the connecting portion 450 is able to be inserted to the first groove 202, and the terminal portion 454 of the connecting portion 450 is able to be inserted to the second groove 302. As such, the connecting member 400 can be connected to the first frame strip 200 and the second frame strip 300. Moreover, the outer surface of the connecting web 430 of the connecting member 400 can be aligned with the outer surfaces of the first frame strip 200 and the second frame strip 300 when the connecting member 400 is connected to the first frame strip 200 and the second frame strip 300. In other words, the connecting web 430 is not bumped out from the first frame strip 200 and the second frame strip 300, leading to a well integrity of the solar cell module. This configuration not only possesses safety consideration, but also improves the beautification of the solar cell module. However, the claimed scope is not limited in this respect.

Reference is made to FIGS. 3 and 5A. In one or more embodiment, the connecting member 400 can further include a spacing plate 460 disposed between the two top wind plates 410 and the bottom wind plate 420, and the spacing plate 460 is connected to the connecting web 430. A portion of the solar panel 100 is disposed between the two top wind plates 410 and the spacing plate 460.

Furthermore, the drainage ditch 404 of the connecting member 400 can expose at least one corner of the solar panel 100. In other words, the rainwater may flow out of the solar cell module along the exposed corner. Therefore, since there is no height difference (step difference) along the flow path of the rainwater, the dust is not stuck in the slits of the step, and the flow of the rainwater is not impeded by the step.

Reference is made again to FIG. 5A. In one or more embodiments, the connecting member 400 can further includes at least one coupling portion 470 connected to the spacing plate 460. The connecting portion 450 is detachably disposed in the accommodating recess 402 via the coupling portion 470. The top wind plates 410, the bottom wind plate 420, the connecting web 430, the spacing plate 460, and the coupling portion 470 can be assembled as a protective packaging. In greater detail, reference is made to FIGS. 5A and 3. The terminal portions 452 and 454 can be respectively coupled to the first groove 202 and the second groove 302 when the connecting member 400 is coupling to the first frame strip 200 and the second frame strip 300. The protective packaging can frame the connecting portion 450 after the connecting portion 450 is fixed to the first frame strip 200 and the second frame strip 300. The protective packaging can be fixed on the connecting portion 450 via the coupling of the coupling portion 470, and the assembly of the connecting member 400 is accomplished.

It is noted that the solar cell module includes four connecting members 400 in FIG. 3, and the claimed scope is not limited in this respect. In other embodiments, the solar cell module may include at least one connecting member 400 to be connected to the first frame strip 200 and the second frame strip 300 while the connection way between other first frame strips 200 and the second frame strips 300 is not limited. Moreover, the shapes of the first frame strip 200 and the second frame strip 300 depend on the shape of the solar panel 100. Basically, an embodiment falls within the scope of the claimed scope if both of the first frame strip 200 and the second frame strip 300 can fix (frame) the solar panel 100.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A solar cell module, comprising:
a solar panel;
at least one first frame strip assembled at an edge of the solar panel;
at least one second frame strip assembled at an edge of the solar panel; and
at least one connecting member, comprising:
two top wind plates, wherein a gap is formed between the two top wind plates;
a bottom wind plate disposed opposite to the two top wind plates;
a connecting web connected to the two top wind plates and the bottom wind plate, the connecting web having a breach and at least one corner, wherein the breach is disposed at the corner and is connected to the gap, such that the breach and the gap form a drainage ditch which exposes at least one corner of the solar panel; and
two connecting terminal portions respectively extending from the connecting web, such that the connecting member is detachably connected to the first frame strip and the second frame strip via the two connecting terminal portions.

2. The solar cell module of claim 1, wherein an angle is formed at the corner of the connecting web of the connecting member, and the angle is about 90 degrees.

3. The solar cell module of claim 1, wherein the two top wind plates of the connecting member are symmetric with respect to the gap.

4. The solar cell module of claim 1, wherein the first frame strip has a first groove, and the second frame strip has a second groove; one of the connecting terminal portions is configured to be inserted to the first groove, and another of the connecting terminal portions is configured to be inserted to the second groove.

5. A solar cell module, comprising:
a solar panel;
at least one first frame strip assembled at an edge of the solar panel;
at least one second frame strip assembled at an edge of the solar panel; and
at least one connecting member detachably connected to the first frame strip and the second frame strip, the connecting member comprising:
two top wind plates, wherein a gap is formed between the two top wind plates;
a bottom wind plate disposed opposite to the two top wind plates;
a connecting web connected to the two top wind plates and the bottom wind plate, such that the two top wind plates, the bottom wind plate, and the connecting web together define an accommodating recess, wherein the connecting web has a breach and at least one corner, and the breach is disposed at the corner and is connected to the gap, such that the breach and the gap form a drainage ditch, and the drainage ditch exposes at least one corner of the solar panel; and
a connecting portion at least disposed in the accommodating recess, and being detachably connected to the first frame strip and the second frame strip.

6. The solar cell module of claim 5, wherein an angle is formed at the corner of the connecting web of the connecting member, and the angle is about 90 degrees.

7. The solar cell module of claim 5, wherein the connecting portion has two terminal portions opposite to each other and respectively extending from the accommodating recess.

8. The solar cell module of claim 7, wherein the first frame strip has a first groove, and the second frame strip has a second groove; one of the terminal portions of the connecting portion is configured to be inserted to the first groove, and another of the terminal portions of the connecting portion is configured to be inserted to the second groove.

9. The solar cell module of claim 5, wherein the two top wind plates of the connecting member are symmetric with respect to the gap, and the connecting member further comprises a spacing plate disposed between the two top wind plates and the bottom wind plate, wherein the spacing plate is connected to the connecting web, and a portion of the solar panel is disposed between the two top wind plates and the spacing plate of the connecting member.

10. The solar cell module of claim 9, wherein the connecting member further comprises:
at least one coupling portion connected to the spacing plate, the connecting portion being detachably disposed in the accommodating recess via the coupling portion.
